(19) United States
(12) Patent Application Publication
(10) Pub. No.: US 2003/0020160 A1
(43) Pub. Date: Jan. 30, 2003

(54) Semiconductor device die and package having improved heat dissipation capability

(76) Inventor: Jeffrey L. Deeney, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 09/915,071

(22) Filed: Jul. 25, 2001

(51) Int. Cl. H01L 23/10

(52) U.S. Cl. 257/706; 257/712; 257/717

(57) ABSTRACT

The overall thermal resistance of a semiconductor device package containing a semiconductor die such as a VLSI IC die is reduced so as to improve the thermal performance of the package without any modification of the basic package structure. An extension of inactive or substantially inactive semiconductor material is added to the die adjacent to the boundary of a heat dissipating active circuit area on the die thereby increasing the effective heat transfer area of the die and establishing a heat spreading flow path to conduct heat away from the active circuit area.

### BACKGROUND OF THE INVENTION

1. Field of the Invention

The present invention relates generally to semiconductor devices such as integrated circuits, and more particularly to the thermal management of such devices.

2. Description of the Related Art

It is well known that many semiconductor packages, whether containing integrated circuits or individual devices such as power transistors, dissipate sufficient heat to require thermal management utilizing heat sinks. In particular, there has been increased emphasis on thermal management in integrated circuit (IC) packaging design stemming from the rapid growth of the number of active circuit elements per chip or die without a corresponding increase in die surface area. The resulting closer spacing of the circuit elements coupled with their higher switching speeds have led to dramatic increases in heat densities. The objective of thermal management in the design of IC packaging is to maintain the operating temperature of the active circuit or junction side of the IC die low enough (for example, 110° C. or below) to prevent premature component failure.

Traditional methods of reducing the maximum junction temperature include lowering the thermal resistance attachment between the die and the package cover/heat spreader, improving heat sink efficiency, increasing package cover thermal conductivity, reducing the thermal resistance between the package cover and heat sink, and/or improving the cooling air flow inside the electronic system incorporating the IC package. For a device with extreme cooling requirements, an active or passive refrigeration system thermally coupled to the cover of the package is sometimes used. These traditional thermal management techniques, however, often increase the size and weight of the electronic system, can be expensive to implement and may risk compromising device reliability.

When surfaces having different thicknesses and conductivities are joined together as in an IC device package, the concept of thermal resistance is useful for analyzing the heat flow. Thus, the overall thermal resistance can be modeled as the sum of three thermal resistances arranged in series between the junction or active circuitry side of the IC die and the outside surface of the cover: the thermal resistance of the die itself, the thermal resistance of the die/cover attachment interface material, typically a conductive epoxy, and the thermal resistance of the cover. The thermal resistances are functions of the thermal conductivities of the materials involved which, for the materials used in IC device packaging, have a broad range. Metals, of course, are the best conductors of heat while the conductive epoxies used, for example, to bond the die to the inside surface of the device cover are the poorest heat conductors. Thus, the thermal bottleneck in removing heat from an IC device is the interface between the IC die and the package cover. The problem of heat dissipation is exacerbated in the case of large, high power IC devices such as very large scale integration (VLSI) integrated circuit central processing units (CPUs). Because the dies of such units are relatively thin (for example, 0.76 mm thick), the IC die itself can provide only limited heat spreading. This can cause significant variations in local heat dissipation on the die surface leading to large surface temperature gradients in the case of a VLSI integrated circuit die having high power circuits along an edge or adjacent a corner thereof. This asymmetry, illustrated by prior art FIGS. 1-4, tends to diminish or may completely eliminate heat spreading through the die in one or two directions.

FIG. 1 shows a simplified cross section view of a conventional integrated circuit device package 10 containing an IC die 12 in the form of a flip-chip VLSI CPU. FIG. 2 is a bottom plan view of the IC die 12. The IC device package 10 includes a package substrate 14 made of a ceramic such as alumina and having an upper surface 16 carrying the IC die 12.

The die 12 basically comprises a substrate 18 of semiconductor material, typically lightly-doped silicon, having a periphery 20 and opposed, parallel, major surfaces, namely, an upper surface 22 and a lower surface 24, also referred to as the junction side or underside of the die 12. In accordance with a typical example of a conventional VLSI CPU, the IC die 12 has a square configuration measuring 22×22 mm, with the periphery 20 thus comprising four edges 20a-20d.

With reference to FIG. 2, formed within an area 26 on the underside 24 of the semiconductor substrate 18 using well-known integrated circuit fabrication techniques, are numerous circuit features including regions defining junctions of active circuit elements. The circuit area 26 occupies essentially the entire surface area of the underside 24 of the semiconductor substrate 18. Thus, the circuit area 26 has a boundary 28 substantially congruent with the periphery 20 of the semiconductor substrate 18. (A very small inactive semiconductor border, that is, a border devoid of active circuit elements typically having a width of about 50-200μ for a 22×22 mm die, may exist around the area 26.) In the example under consideration, high power active circuit elements, shown schematically as a block 29, within the area 26 adjoin the portion of the boundary 28 immediately adjacent the edge 20a.

With reference again to FIG. 1, the IC die 12 is mechanically and electrically connected to the upper surface 16 of the package substrate 14 by means of an underfilled control collapse chip connection (C4) 30 coupling the junction side 24 of the die 12 to metalization on the upper surface 16 of the package substrate 14. The space between the die underside 24 and the upper surface 16 of the package substrate is filled with a compliant, non-conductive epoxy 32. As is known in the art, in C4 technology the die is flipped upside down to provide direct, very low inductance electrical connections between the circuit elements on the underside 24 of the die and the package substrate 14.

In the example under consideration, the underside 24 of the IC die has a land grid array (LGA) of signal pads or contacts in registration with a matching array of pads or contacts on the upper surface 16 of the package substrate 14. The package substrate 14 typically comprises a multilayer assembly that interconnects the LGA on the upper surface of the package substrate 14 with a larger LGA of signal pads on the underside of the package substrate. This physically larger LGA may be connected to a host or higher assembly such as a printed circuit board 36 by means of an LGA interposer socket 38.

A cover 40 is attached to the package substrate 14 and includes an inner surface 42 defining with the upper surface 16 of the package substrate 14 an interior cavity or space 44 enclosing the IC die 12. The cover 40 is fabricated of a heat conductive material such as aluminum silicon carbide. A compliant heat transfer interface 46, such as a silver filled epoxy, is interposed between and thermally couples the upper surface 18 of the semiconductor die 12 and the inner surface 42 of the cover 40.

FIG. 3 shows an example of the asymmetric power distribution seen on the junction side 24 of the large integrated circuit die 12 depicted in FIGS. 1 and 2 and having high power circuits along the edge 20a. As can be seen from the power map in FIG. 3, there are large variations in power density or heat flux across the integrated circuit die underside, with the highest concentration thereof existing along the edge 20a adjacent the high power circuits.

Through the use of thermal modeling, the temperature distribution across the junction side of the IC die can be mapped, as shown (in ° C.) in FIG. 4, based on the power map of FIG. 3. As expected, the higher power densities along the edge 20a of the die 12 result in higher temperatures along that edge, and operating temperature gradients of 30 to 40° C., or more, across the die are not uncommon.

### SUMMARY OF THE INVENTION

The present invention reduces the overall thermal resistance of a semiconductor device package so as to improve the thermal performance of the package without any modification of the basic package structure.

Broadly, in accordance with one exemplary embodiment of the invention, there is provided a semiconductor die comprising a pair of opposed parallel major surfaces and a periphery; an active circuit area within a boundary on one of the major surfaces of the semiconductor die, the active circuit area comprising at least one active circuit element that dissipates heat during operation; and a heat spreading extension disposed between at least a portion of the boundary and at least a portion of the die periphery adjacent the boundary portion, the extension being operable to establish a heat flow path to conduct heat away from the at least one heat dissipating active circuit element.

Pursuant to another specific embodiment of the invention, there is provided a semiconductor package comprising a package substrate having an upper surface; a thermally conductive cover secured to the package substrate, the cover including an inner surface, the inner surface of the cover and the upper surface of the package substrate defining a space; and a semiconductor die enclosed within the space, the semiconductor die having a major surface and a periphery, the surface of the semiconductor die including an active circuit area comprising at least one active circuit element dissipating heat during operation of the semiconductor package, the active circuit area having a boundary, the surface of the semiconductor die being thermally coupled to the inner surface of the cover and wherein the die includes a heat spreading extension integral with the die, the heat spreading extension being disposed between the boundary of the active circuit area and the periphery of the die, the heat spreading extension being operable to establish a heat flow path to conduct heat away from the at least one active circuit element.

### BRIEF DESCRIPTION OF THE DRAWINGS

Further objects, features and advantages of the present invention will become apparent from the detailed description of the preferred embodiments, below, when taken in conjunction with the accompanying drawings in which:

FIG. 1 is a schematic side elevation view, in cross section, showing a conventional integrated circuit package;

FIG. 2 is a bottom plan view of the junction side of the IC die incorporated in the package of FIG. 1, as seen along the line 2-2 in FIG. 1;

FIG. 3 is a power density map for a conventional IC die such as that shown in FIGS. 1 and 2;

FIG. 4 is the predicted junction temperature map for the power density map of FIG. 3;

FIG. 5 is a schematic side elevation view, in cross section, of an integrated circuit package in accordance with a first preferred embodiment of the invention;

FIG. 6 is an enlarged, side elevation view of a portion of the package shown in FIG. 5;

FIG. 7 is a bottom plan view of the junction side of the IC die incorporated in the package of FIG. 1, as seen along the line 7-7 in FIG. 5;

FIG. 8 is a graph showing a specific example of the cooling effect derived from the present invention;

FIG. 9 is a bottom plan view of the junction side of an IC die in accordance with a second preferred embodiment of the invention; and

FIG. 10 is a bottom plan view of the junction side of an IC die in accordance with a third preferred embodiment of the invention.

### DETAILED DESCRIPTION OF THE INVENTION

Although the invention will be described in detail in the context of a flip-chip VLSI integrated circuit device package, it will be obvious to those skilled in the art that the invention has broader utility, being applicable to a wide range of semiconductor packages including those for individual high power density semiconductor devices such as high power transistors and laser diodes.

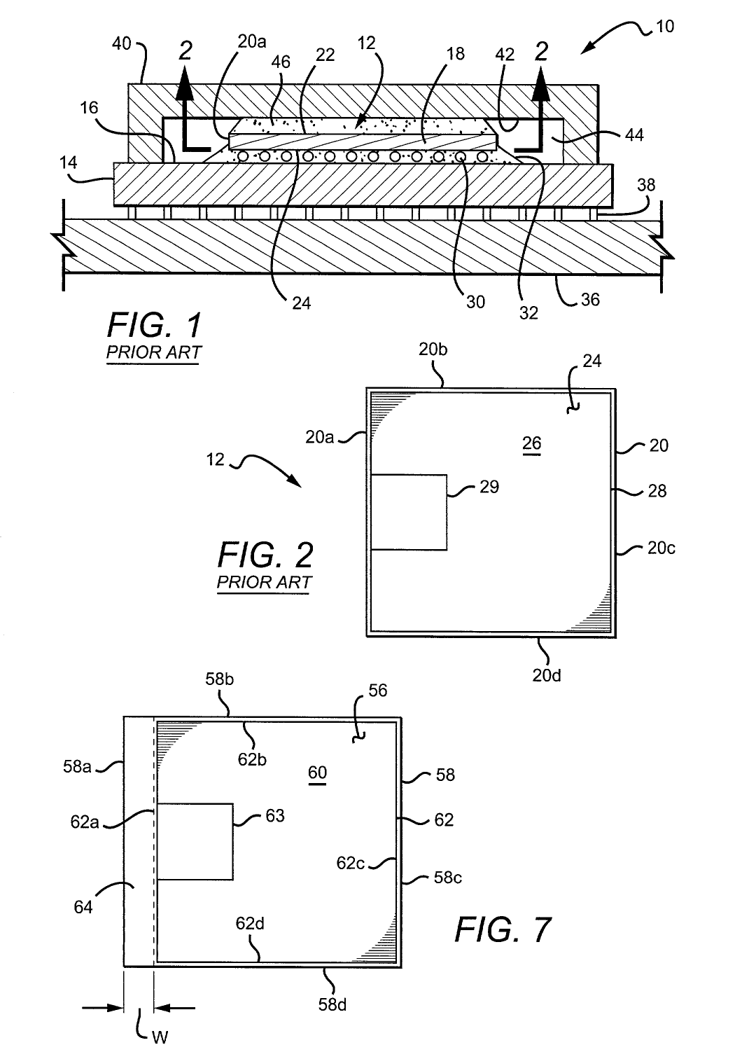

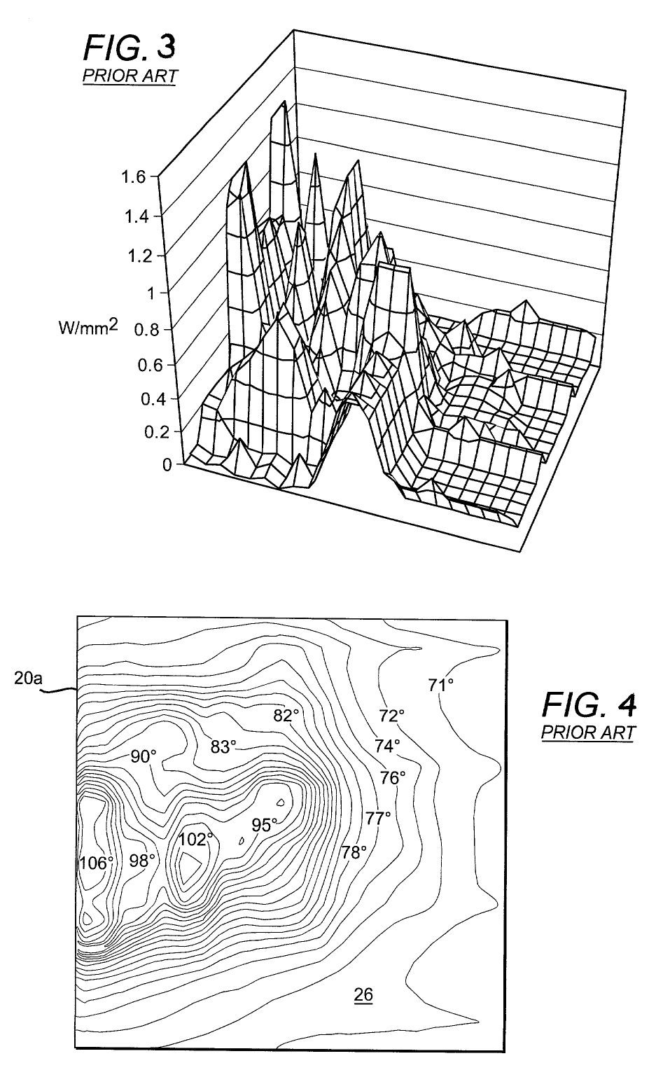

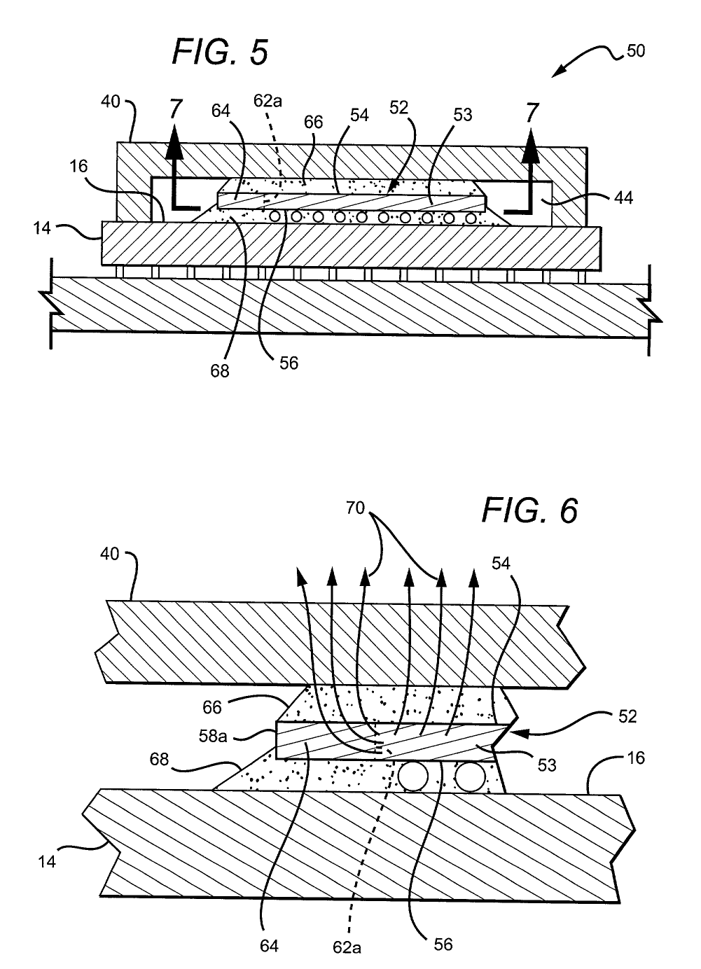

In the description of FIGS. 5, et seq., which follows, the same reference numerals used in connection with prior art FIGS. 1 and 2 will be used to designate like elements.

FIG. 5 shows, in simplified form, a semiconductor device package 50 in accordance with a first, preferred embodiment of the invention, enclosing a semiconductor die 52 which, as before, may take the form of an integrated circuit such as a flip-chip VLSI CPU. Except for the die 52, the package 50, structurally and dimensionally, is basically the same as the conventional package 10, thus including a package substrate 14 having an upper surface 16; a cover 40; and an interior space 44. The IC die 52 device is mounted on the upper surface 16 of the package substrate 14 within the space 44 in the manner described earlier.

Referring now also to FIGS. 6 and 7, the IC die 52 basically comprises a semiconductor substrate 53 including upper and lower major sides 54 and 56, respectively, and a periphery 58. In accordance with the specific example under consideration, the IC die 52 has a rectangular or square configuration in plan view, including four edges 58a-58d. The underside 56 of the IC die 52 comprises the junction side of the die, that is, the side incorporating the active circuitry of the integrated circuit. As in the conventional IC described in connection with FIGS. 1 and 2, the active circuitry is contained within an area 60 having a boundary 62. The area 60, in accordance with the specific example under consideration, has a square or rectangular configuration bounded by four lines 62a-62d paralleling respective ones of the peripheral edges 58a-58d of the die 52. The boundary lines 62b-62d substantially coincide with the edges 58b-58d, respectively.

The active circuit area 60, including its dimensions and circuit contents, is conventional and the same as already described. Thus, high power dissipation active circuit elements, represented by a block 63, are disposed along one the boundary line 62a paralleling the peripheral edge 58a of the die 52.

In accordance with the invention, the portion of the die between the boundary line 62a and the edge 58a comprises a heat spreading extension 64 of inactive semiconductor substrate material. The extension 64 extends along the entire length of the boundary line 62a and has a width, w, which may measure 1 mm by way of example and not limitation, for an IC die 0.76 mm thick and having an active circuit area 60 measuring 22×22 mm. The extension 64 serves during operation of the integrated circuit package 50 to establish a thermal energy flow path to spread and conduct heat away from the active circuit area 60 and to transfer that heat to the cover 40 via a heat transfer interface 66 for dissipation to the ambient environment. A similar heat transfer interface 68 couples the underside of the die and the upper surface 16 of the package substrate 14.

As before, the heat transfer interface 66 comprises a compliant, conductive epoxy such as a silver filled epoxy, while the interface 68 comprises a compliant, non-conductive epoxy. The thermal interfaces 66 and 68 above and below the IC die extend across the entire upper and lower major surfaces 54 and 56 of the integrated circuit die 52 including the heat-spreading extension 64 formed thereon. As shown in the enlargement of FIG. 6, heat, represented by the arrows 70, is thus transferred from the active circuit area 60 into the extension 64 and from there through the heat transfer interface 66 to the cover 40 of the device package.

The extension 64 is created during the manufacture of the die in the wafer form. During the wafer sawing operation, the wafer is cut in such a manner that an inactive margin of semiconductor remains adjacent to the high power circuit boundary 62a to form the extension 64.

In some cases this approach might increase the cost of the integrated circuit by reducing the number of dies that can be placed on a single wafer. However, any increased cost is outweighed by the device cooling made available through the present invention which reduces or may even eliminate the need for any of the cooling enhancements mentioned earlier.

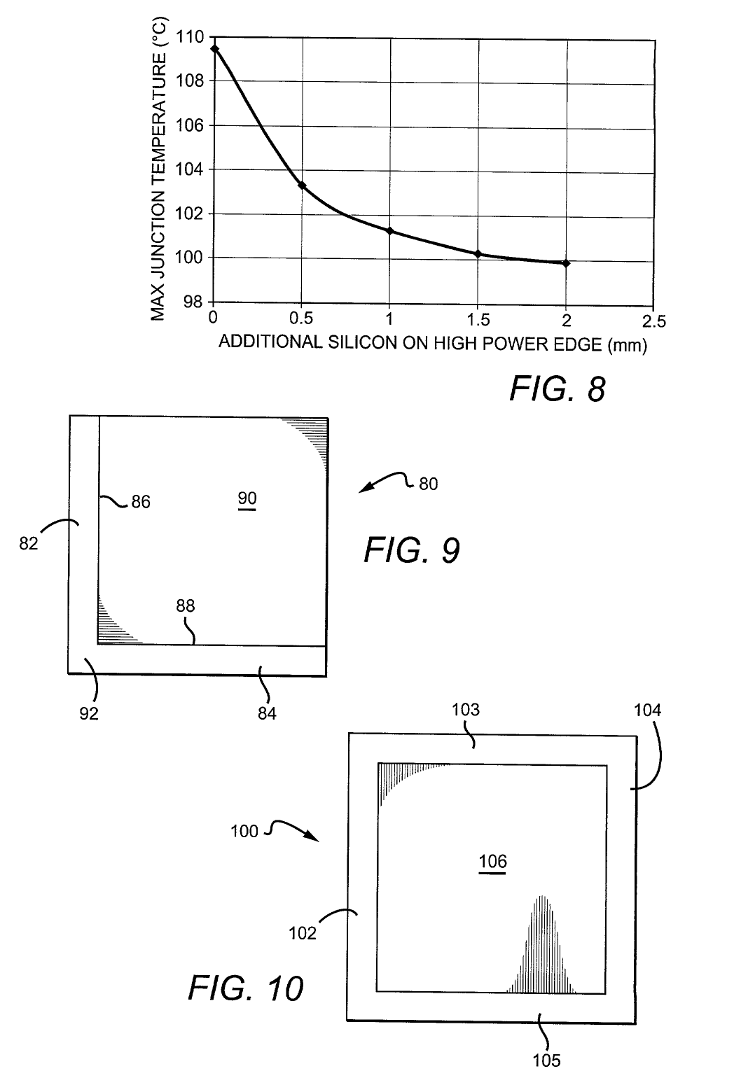

As will be evident to those skilled in the art, the cooling benefits afforded by the present invention will vary with the design and power distribution of the semiconductor device. FIG. 8 is a graph showing the cooling effect imparted by an extension of inactive semiconductor material for a 0.76 mm thick VLSI CPU of a specific design and a specific power distribution across an active circuit area having a high temperature region adjoining one of the boundaries. It will be seen that for the specific example that is the subject of FIG. 8, the addition of an extension of even a modest width, w, of, for example, 1 mm to 1.5 mm by itself significantly decreases the maximum junction temperature.

FIG. 8 shows that for a given die thickness, the cooling benefit obtained diminishes as the width of the extension increases. Also, it will be evident that the increased amount of heat spreading provided by the extension is a function of both the die thickness and the width of the extension. Thus, as another example, a die having a thickness of 0.38 mm would benefit substantially from an extension having a width of only 0.4 to 0.5 mm.

FIGS. 9 and 10 show alternative, preferred embodiments of the invention. FIG. 9 depicts a die 80 having extensions 82 and 84 of inactive semiconductor material projecting from two adjacent boundaries 86 and 88 of an active circuit area 90, as well as from the corner 92 shared by those boundaries. FIG. 10 shows a square die 100 having four extensions 102-105 provided around an entire active circuit area 106, including the corners thereof. The addition of extensions about the entire boundary of an active circuit area may be especially advantageous for small, high power semiconductor devices such as high power transistors and laser diodes that are individually packaged. Additional extension configurations will suggest themselves to those skilled in the art depending upon the heat transfer requirements of a particular device.

It will be evident to those skilled in the art that instead of forming the die extension(s) from inactive semiconductor material that is completely inactive, low power dissipation circuit elements could be carried by the extension. Significant heat spreading benefits could thereby still be obtained.

I claim:

1. A semiconductor die comprising:
a pair of opposed parallel major surfaces and a periphery;
an active circuit area within a boundary on at least one of the major surfaces of the semiconductor die, said active circuit area comprising at least one active circuit element that dissipates heat during operation; and a heat spreading extension disposed between at least a portion of said boundary and at least a portion of said die periphery adjacent said boundary portion, said extension being operable to establish a heat flow path to conduct heat away from said at least one heat dissipating active circuit element.

2. The semiconductor die defined in claim 1, in which:
said extension is devoid of heat dissipating active circuit elements.

3. The semiconductor die defined in claim 1, in which:
said heat spreading extension is disposed between the entire extent of said boundary and the entire extent of said periphery.

4. The semiconductor die defined in claim 1, in which:
said semiconductor die comprises an integrated circuit die, and in which said periphery comprises a plurality of edges, the at least one active circuit element being adjacent said portion of said boundary, said extension being disposed between said portion of said boundary and one of the plurality of said edges of the periphery.

5. A semiconductor die comprising:
a pair of opposed parallel major surfaces and a periphery;
an active circuit area on one of the major surfaces of the semiconductor die, said active circuit area having a boundary within said periphery and comprising at least one active circuit element that dissipates substantial heat during operation, said at least one active circuit element being disposed adjacent a portion of said boundary; and
a heat spreading extension disposed between at least said portion of said boundary and an adjacent portion of said die periphery, said extension being operable to establish a heat flow path to conduct heat away from said at least one heat dissipating active circuit element.

6. The semiconductor die defined in claim 5, in which:
said heat spreading extension is devoid of heat dissipating active circuit elements.

7. The semiconductor die defined in claim 5, in which:
said semiconductor die comprises an integrated circuit die, and in which said periphery comprises a plurality of edges, said extension being disposed between said portion of said boundary and one of the edges of the periphery.

8. A semiconductor package comprising:
a package substrate having an upper surface;
a thermally conductive cover secured to said package substrate, said cover including an inner surface, said inner surface of said cover and said upper surface of said package substrate defining a space; and
a semiconductor die enclosed within said space, said semiconductor die having a major surface and a periphery, said surface of said semiconductor die including an active circuit area comprising at least one active circuit element dissipating heat during operation of the semiconductor package, said active circuit area having a boundary, said surface of said semiconductor die being thermally coupled to said inner surface of said cover and wherein the die includes a heat spreading extension integral with the die, said heat spreading extension being disposed between said boundary of said active circuit area and said periphery of said die, said heat spreading extension being operable to establish a heat flow path to conduct heat away from said at least one active circuit element.

9. The semiconductor package defined in claim 8, in which:
said heat spreading extension is devoid of active circuit elements.

10. The semiconductor package defined in claim 8, which includes:
a heat transfer interface thermally coupling said surface of said semiconductor die and said inner surface of said cover, said heat spreading extension being operable to transfer said heat to said cover via said heat transfer interface.

11. The semiconductor package defined in claim 8, in which:
said semiconductor die comprises an integrated circuit die.

12. The semiconductor package defined in claim 11, in which:
said surface of said integrated circuit die confronts said upper surface of said package substrate, and in which said die includes a second major surface opposed to and parallel with the first mentioned major surface, said second major surface confronting said inner surface of said cover and being thermally coupled thereto.

13. The semiconductor package defined in claim 11, in which:
said periphery comprises a plurality of edges, said at least one active circuit element being disposed adjacent a portion of said boundary proximate one of said plurality of edges, said heat spreading extension being dispose between said portion of said boundary and said one of said plurality of said edges.
